(19) United States
(12) Patent Application Publication
(10) Pub. No.: US 2015/0184278 A1
(43) Pub. Date: Jul. 2, 2015

(54) PLASTIC FILM COATED WITH ZINC TIN OXIDE AND HAVING IMPROVED OPTICAL ABSORPTION PROPERTY

(71) Applicant: Bayer MaterialScience AG, Monheim Am Rhein (DE)

(72) Inventors: Peter Reichert, Dormagen (DE); Steffen Günther, Dresden (DE); Tobias Vogt, Dresden (DE)

(73) Assignee: Bayer MaterialScience AG, Monheim Am Rhein (DE)

(21) Appl. No.: 14/404,045

(22) PCT Filed: May 28, 2013
(86) PCT No.: PCT/EP2013/060932

§ 371 Date: Nov. 26, 2014

(30) Foreign Application Priority Data
May 31, 2012 (EP) 12170145.2

(51) Int. Cl. C23C 14/08; C23C 14/34

(52) U.S. Cl. CPC C23C 14/086; C23C 14/34

(57) ABSTRACT

The present invention provides a coated plastics film with a zinc tin oxide coating which has improved absorption property, in particular in the blue spectral range from 380 to 430 nm, the zinc tin oxide coating itself and a process for the production thereof, and an electronic device comprising a corresponding coated plastics film.

The present invention provides a coated plastics film with a zinc tin oxide coating which has improved absorption property, in particular in the blue spectral range from 380 to 430 nm, the zinc tin oxide coating itself and a process for the production thereof, and an electronic device comprising a corresponding coated plastics film.

The production of flexible electronics requires in particular flexible substrates which protect the electronic devices from the influence of oxygen and water vapour. Such oxygen and water vapour barriers are achieved by correspondingly coating flexible plastics substrates, in particular plastics films. Inorganic coatings such as aluminium oxide, titanium dioxide or silicon nitride, for example, are known as suitable coatings for such barrier coatings. According to EP 2 148 899 A1, zinc tin oxide (ZTO) is also suitable as an inorganic barrier coating for plastics substrates, for example for the packaging of foodstuffs. According to EP 2 148 899 A1, such a coating has the advantage over aluminium oxide and silicon nitride of less cracking on application to flexible plastics substrates.

In addition to the required property of forming a satisfactory barrier to the permeation of oxygen and water vapour, the flexible substrates must, however, exhibit good transmission in the visible spectral range for use in flexible electronic devices. To that end, the absorption must not increase significantly in any range in that spectral range, because locally increased absorptions in the visible spectral range in the device lead to a colour shift and hence to a false colour impression. ZTO, however, has the disadvantage of increased absorption in the blue spectral range below 430 nm, which leads to a yellowish colour impression in the coating and is therefore undesirable for use in electronic devices. A conventional ZTO coating, as is described, for example, in EP 2 148 899 A1, in a layer thickness of 90 nm, for example, has an absorption of more than 4% in the spectral range from 380 to 430 nm.

There was therefore a need to improve the absorption property of such ZTO coatings and accordingly also of the coated substrates, in particular also to enable their use as barrier-coated substrates in flexible electronic devices.

It is known from B.-Y. Oh et al., Journal of Crystal Growth 281 (2005) 475-480 that aluminium-doped zinc oxide layers (ZnO:A1) applied by sputtering, which are used as transparent conductive coatings, exhibit improved electrical and optical properties in the spectral range from 300 to 700 nm as a result of subsequent thermal treatment with hydrogen. To that end, the coatings must, however, be treated in a hydrogen atmosphere for from 10 to 120 minutes at a temperature of 300° C. An effect of such H₂ after-treatment on zinc tin oxide barrier coatings is not known, however. In addition, such after-treatment is not only an additional, very expensive process step for large-scale production, but also, owing to the use of pure hydrogen at relatively high temperatures, a considerable safety risk which would require process-related safety measures, such as, for example, corresponding sealing of such a system. In a continuous production process, such after-treatment would therefore be impossible to carry out or could he carried out only with a considerable outlay. In addition, such after-treatment is not suitable for plastics substrates owing to the high temperatures.

Accordingly, the object underlying the invention was to provide a substrate coated with a ZTO barrier coating, and a ZTO barrier coating, the optical absorption property of which are improved as compared with known ZTO coatings, and to find a simple process for the production thereof

Surprisingly, the object was achieved by carrying out the deposition of such a ZTO coating by means of a sputtering process in the presence of hydrogen in the process gas.

It has surprisingly been found that the presence of H₂ in the process gas yields barrier coatings which, on the one hand, have a low absorption coefficient in the spectral range from 380 to 430 nm and the barrier properties of which, on the other hand, are nevertheless equally as good as those of barrier layers produced in the conventional manner without hydrogen in the process gas. This is unexpected to the person skilled in the art, because the presence of H₂ in the process gas leads to a pressure increase, which in turn brings about an increase in the porosity of the resulting barrier layer. Increased porosity can adversely affect the barrier properties of the layers, and it was extremely surprising that this is not the case with the coated plastics substrates according to the invention.

Accordingly, the present invention provides a coated plastics substrate comprising a base layer comprising at least one plastics material, preferably at least one thermoplastic plastics material, and at least one coating of zinc tin oxide, characterised in that the coating of zinc tin oxide is produced in a sputtering process in the presence of hydrogen in the process gas.

The coating of zinc tin oxide can be located directly on the base layer comprising at least one plastics material, preferably at least one thermoplastic plastics material. It is, however, also possible according to the invention for further layers to be located between the base layer and the coating of zinc tin oxide.

The present invention further provides a permeation barrier coating for gases and vapours, preferably for oxygen, nitrogen and/or water vapour, particularly preferably for oxygen and/or water vapour, based on zinc tin oxide, characterised in that the coating of zinc tin oxide is produced in a sputtering process in the presence of hydrogen in the process gas. The coating according to the invention can additionally be an additional permeation barrier coating for nitrogen.

Such a zinc tin oxide coating surprisingly has significantly lower absorption in the blue spectral range from 380 to 430 nm, and accordingly a lesser yellow tinge, than coatings produced without the addition of hydrogen to the process gas. It was possible to reduce the absorption in that spectral range to less than 5%, preferably to less than 4%. That effect on the absorption property of the ZTO coating by the addition of hydrogen to the process gas in the sputtering process is all the more surprising since a pure hydrogen atmosphere is not required, as in B.-Y. Oh el al., but even comparatively small amounts of hydrogen in the process gas are sufficient to improve the absorption. In addition to hydrogen, the process gas in the production by the sputtering process comprises at least one noble gas, preferably argon. Particularly preferably, the process gas in the production by the sputtering process additionally comprises oxygen.

The process gas comprises preferably from 0.1 to 20 vol. %, particularly preferably from 0.5 to 15 vol. %, most particularly preferably from 1 to 12 vol. % hydrogen. The vol. % figures are based on the total volume of the process gas including any noble gases that may be present.

The zinc tin oxide in the coating is preferably a chemical compound of the elements zinc, tin and oxygen, wherein the amount by mass of zinc is from 5 to 70%, preferably from 10 to 70%.

Also preferably, the zinc tin oxide is ZnSnₓO_{y}, wherein x represents a number from 0.2 to 10,0 and y represents a number from 1.4 to 21,0. Such zinc tin oxides are so-called mixed oxides with different amounts of phases ZnSnO₃, Zn₂SnO₄ and optionally additionally ZnO and SnO₂ and optionally unreacted Zn and Sn.

In order to improve the barrier properties, one or more coatings of zinc tin oxide can be applied to the substrate. In specific embodiments of the invention, the coatings of zinc tin oxide can also alternate with other layers. The thickness of the coating of zinc tin oxide is in each case from 10 to 1000 nm, preferably from 20 to 500 nm, particularly preferably from 50 to 250 nm. In the case of a plurality of coatings of zinc tin oxide, they can be of the same composition or different compositions ZnSnₓO_{y}. In preferred embodiments of the invention, the composition ZnSnₓO_{y} in the individual zinc tin oxide coatings is substantially the same. In addition, in the case of a plurality of coatings, the layer thicknesses of the individual zinc tin oxide coatings can be the same or different. In preferred embodiments of the invention, the layer thickness of each of the individual zinc tin oxide coatings is the same. In addition, in the case of a plurality of coatings, the interfaces between the layers can be a sharp interface (composition change across the interface is disruptive) or can be a continuous interface (composition change across the interface is continuous over predetermined distance)

In the spectral range from 380 to 430 nm, the zinc tin oxide coating preferably has an absorption coefficient of less than 0.5 l/μm, particularly preferably of less than 0.3 l/μm. The absorption coefficients can be determined by measuring the transmission and reflection using a conventional spectrometer, calculating the absorption from the measured data, and determining therefrom the mean value of the absorption in the spectral range from 380 to 430 nm in question. The absorption coefficient can be calculated therefrom using the layer thickness.

The plastics substrate, preferably thermoplastic plastics substrate, comprising a base layer comprising at least one plastics material, preferably at least one thermoplastic plastics material, is preferably a flexible plastics substrate, particularly preferably a single- or multi-layer plastics film, The plastics substrate is preferably a plastics substrate that comprises a base layer comprising at least one thermoplastic plastics material. A multi-layer thermoplastic plastics film as substrate can be a thermoplastic plastics film produced by means of co-extrusion, extrusion lamination or lamination, preferably a thermoplastic plastics film produced by means of co-extrusion. The single- or multi-layer plastics film comprising a base layer has a thickness of preferably from 10 μm to 1000 μm, particularly preferably from 20 to 500 μm, most particularly preferably from 50 to 300 μm.

Suitable thermoplastic plastics materials for the plastics layers are, independently of one another, thermoplastic plastics materials selected from polymers of ethylenically unsaturated monomers and/or polycondensation products of bifunctional reactive compounds. Transparent thermoplastic plastics materials are particularly preferred.

Particularly suitable thermoplastic plastics materials are poly⁻carbonates or copolycarbonates based on diphenols, poly- or copoly-acrylates and poly- or copoly-methaerylates, such as, for example and preferably, polymethyl methacrylate, polymers or copolymers with styrene, such as, for example and preferably, transparent polystyrene or polystyrene acrylonitrile (SAN), transparent thermoplastic polyurethanes, and also polyolefins, such as, for example and preferably, transparent polypropylene types or polyolefins based on cyclic olefins (e.g. TOPAS , Hoechst), poly- or copoly-condensation products of terephthalic acid or naphthalenedicarboxylic acid, such as, for example and preferably, poly- or copoly-ethylene terephthalate (PET or CoPET), glycol-modified PET (PETG) or poly- or copoly-butylene terephthalate (PBT or CoPBT), poly- or copoly-ethylene naphthalate (PEN or CoPEN) or mixtures of the above.

The thermoplastic plastics materials are preferably polyearbonates or copolycarbonates based on diphenols, poly- or copoly-acrylates, poly- or copoly-methacrylates, polymers or copolymers with styrene, thermoplastic polyurethanes, polyolefins, copolycondensation products of terephthalic acid, poly- or copoly-condensation products of naphthalenedicarboxylic acid, or mixtures thereof.

In one embodiment of the invention, the at least one thermoplastic plastics material does not comprise polyethylene terephthalate.

Particular preference is given to those thermoplastic plastics materials that have high transparency and a low haze value because they are particularly suitable for optical and optoelectronic applications, such as, for example, in display' applications. Such thermoplastic plastics materials are particularly preferably polycarbonates or copolycarbonates based on diphenols, poly- or copoly-acrylates, poly- or copoly-methacrylates, or poly- or copoly-condensation products of terephthalic acid or naphthalenedicarboxylic acid, such as, for example and preferably, poly- or copoly-ethylene terephthalate (PET or CoPET), glycol-modified PET (PETG), or poly- or copoly-butylene terephthalate (PBT or CoPBT), poly- or copoly-ethylene naphthalate (PEN or CoPEN) or mixtures of the above.

Such plastics films and their production are known to the person skilled in the art and in addition are commercially available.

In preferred embodiments of the present invention, a smoothing layer can be applied to the surface that is to be coated of the plastics substrate, preferably of the plastics film. Such a smoothing layer preferably has a surface roughness (measured as the Ra value (average roughness)) of less than 500 nm, particularly preferably of less than 200 nm, most particularly preferably of less than 150 nm. In preferred embodiments, such a smoothing layer has a surface roughness of less than 100 nm, preferably of less than 50 am, particularly preferably of less than 20 nm. The surface roughness of such a smoothing layer can be measured according to DIN EN ISO 4287 using a Contour GT-KO Optical Surface-profiler. Such a prior application of such smoothing layers can have the advantage that fewer defects are produced in the zinc tin oxide coating and better permeation barriers for gases and vapours, preferably for oxygen and/or water vapour, can accordingly be achieved.

Suitable materials for such smoothing layers are known to the person skilled in the art. They can be, for example, coating compositions for a radiation-cured coating or a polyurethane- or epoxy-resin-based coating. Preference is given to materials for radiation-cured coatings, in particular those based on acrylates.

Radiation-cured coatings are preferably obtainable from coating compositions comprising radiation-curable polymers and/or monomers.

Suitable radiation-crosslinkable polymers are in particular those polymers that can be crosslinked by means of electromagnetic radiation, for example by means of UV rays, electron beams, X-rays or gamma rays, preferably by means of UV radiation or electron beams. Particular preference is given to polymers carrying ethylenically unsaturated groups which can be crosslinked by means of radiation. Such ethylenically unsaturated groups can be, for example, acrylate, methacrylate, vinyl ether, allyl ether and maleimide groups. Suitable ethylenically unsaturated polymers are, for example and preferably, (meth)acrylated poly(meth)acrylates, polyurethane (meth)acrylates, polyester (meth)acrylates, polyether (meth)acrylates, epoxy (meth)acrylates, (meth)acrylated oils and unsaturated polyesters. (R. Schwalm, UV Coatings, 2007, Elsevier, p. 93-139). Particularly preferred ethylenically unsaturated polymers are (meth)acrylated poly(meth)acrylates or polyurethane (meth)acrylates.

Suitable radiation-crosslinkable monomers are in particular those monomers that can be crosslinked by means of electromagnetic radiation, for example by means of UV rays, electron beams, X-rays or gamma rays, preferably by means of UV radiation or electron beams. They are preferably unsaturated monomers. Unsaturated monomers can preferably be acrylates or methacrylates, preferably C₁-C₂₀-alkyl acrylates or C₁-C₂₀-alkyl methacrylates, vinyl aromatic compounds, preferably C₁-C₂₀-vinyl aromatic compounds, such as, for example, styrene, vinyltoluene, α-butylstyrene or 4-n-butylstyrene, vinyl esters of carboxylic acids, preferably vinyl esters of C₁-C₂₀-carboxylic acids, such as, for example, vinyl laurate, vinyl stearate, vinyl propionate and vinyl acetate, vinyl ethers, preferably vinyl ethers of C₁-C₂₀-alcohols, such as, for example, vinyl methyl ether, vinyl isobutyl ether, vinyl hexyl ether or vinyl octyl ether, unsaturated nitrites, such as, for example, acrylonitrile or methacrylonitrile, or an alkene with one or more double bonds, preferably one or two double bonds, preferably C₂-C₂₀-alkenes with one or more double bonds, preferably one or two double bonds, such as, for example, ethylene, propylene, isobutylene, butadiene or isoprene. The radiation-crosslinkable monomers are particularly preferably acrylates or methacrylates, preferably C₁-C₂₀-alkyl acrylates or C₁-C₂₀-alkyl methacrylates.

Suitable examples of such acrylates or methacrylates, preferably C₁-C₂₀-alkyl acrylates or C₁-C₂₀-alkyl methacrylates, are methyl acrylate, ethyl acrylate, n-butyl acrylate, isobutyl acrylate, tert-butyl acrylate, 2-ethyl-hexyl acrylate, isodecyl acrylate, acrylate, C₁₂-C₁₅-alkyl acrylates, n-stearyl acrylate, n-butoxyethyl acrylate, butoxy diethylene glycol acrylate, methoxy triethylene glycol acrylate, cyclohexyl acrylate, tetrahydrofurfuryl acrylate, benzyl acrylate, 2-phenoxyethyl acrylate, isobornyl acrylate, 2-hydroxyethyl acrylate, 2-hydroxypropyl acrylate, 2-hydroxyethyl acrylate, 2-hydroxybutyl acrylate, 2-hydroxybutyl acrylate, methanediol diacrylate, glycerol diacrylate, neopentyl glycol diacrylate, 2-butyl-2-ethyl-1,3-propanediol diacrylate, trimethylolpropane diacrylate, pentaerythritol triacrylate, glycerol triacrylate, 1,2,4-butanetriol. triacrylate, trimethylolpropane triacrylate, tricyclodecanedimethanol diacrylate, ditrimethylolpropane tetraacrylate, pentaerythritol tetraacrylate, dipentaerythritol tetraacrylate, dipentaerythritol. pentaacryiate, dipentaerythritol hexaacrylate and the corresponding methacrylates. The alkoxylated, preferably ethoxylated, acrylates and methacrylates mentioned above are additionally suitable as acrylates and methacrylates.

The coating composition for such smoothing layers that is used for coating the base film preferably comprises at least one suitable photoinitiator. The photoinitiator can also he bonded covalently to the crosslinkable polymer. The radiation-induced polymerisation is preferably carried out by means of radiation having a wavelength of from 400 nm to 1 pm, such as, for example, UV rays, electron beams, X-rays or gamma rays.

When UV radiation is used, curing is initiated in the presence of photoinitiators. As regards photoinitiators, a distinction is made in principle between two types, the unimolecular type (I) and the bimolecular type (II). Suitable type (1) systems are aromatic ketone compounds, such as, for example, benzophenones in combination with tertiary amines, alkylhenzophenones, 4,4-bis(dimethylamino)benzophenone (Michler's ketone), anthrone and halogenated benzophenones or mixtures of the mentioned types. Also suitable are type (II) initiators such as benzoin and its derivatives, benzil ketals, acylphosphine oxides, 2,4,6-trimethylbenzoyl-diphenylphosphine oxide, bisacylphosphine oxide, phenyiglyoxylic acid esters, camphorquinone, α-aminoalkylphenones, α,α-dialkoxyacetophenones and α-hydroxyalkylphenones. Photoinitiators that can readily be incorporated into the aqueous dispersions are preferred. Such products are, for example, Irgacure® 500 (a mixture of benzophenone and (1-hydroxycyclohexyl)phenyl ketone, BASF SE, Ludwigshafen, DE), Irgacure® 819 DW (phenylbis-(2,4,6-trimethylbenzoyl)phosphine oxide, BASF SE, Ludwigshafen, DE), Esacure® KIP EM (oligo-[2-hydroxy-2-methyr1-[4-(1-methylvinyl)-phenyl]-propanone], Lainberti, Aldizzate, Italy). Mixtures of those compounds can also be used.

The coating of zinc tin oxide is preferably a permeation barrier layer for gases and vapours, particularly preferably for oxygen, nitrogen and/or water vapour, most particularly preferably for oxygen and/or water vapour, particularly preferably for oxygen and water vapour.

An antireflection layer can preferably be applied to the outermost layer, or to the coating of zinc tin oxide, in the coated film according to the invention. The transmission of the plastics substrates, preferably plastics films, coated according to the invention can be additionally increased by such an antireflection layer. Such layers are known to the person skilled in the art. They can be, for example, layers of materials with a. low refractive index, such as, for example, SiO₂MgF₂ or the like, complex multi-layer structures in which thin layers of materials with different refractive indices alternate, or layers with a refractive index gradient.

The plastics substrates, preferably plastics films, coated according to the invention preferably have a transmission in the visible spectral range of more than 75%, particularly preferably of more than 80%. Most particularly preferably the plastics substrates coated according to the invention can also have a transmission in the visible spectral range of more than 85%, preferably even of more than 90%, in particular in combination with an additional antireflection layer.

The plastics substrates, preferably plastics films, coated according to the invention preferably have an oxygen permeability of less than 0.5 cm³/m²/day, particularly preferably of less than 0.1 cm³/m²/day, and/or a water vapour permeability of less than 0.1 g/m²/day, particularly preferably of less than 0.01 g/m²/day.

The plastics substrates, preferably plastics films, coated according to the invention can be produced in a simple process without additional complex after-treatment steps. In particular, a continuous procedure via a roll-to-roll process is possible.

The present invention further provides a process for the production of a plastics substrate coated according to the invention, preferably of a coated plastics film, wherein at least one coating of zinc tin oxide is applied to a plastics substrate, preferably a plastics film, by means of a sputtering process in vacuo, characterised in that the process gas comprises hydrogen.

Suitable targets (electrodes) for the sputtering process are preferably those made of an alloy at least comprising zinc and tin or those at least comprising zinc tin oxide. Where a zinc tin oxide target is used, it may also comprise further additives, such as, for example, nitrogen, in small amounts.

In addition to hydrogen, the process gas in the production by the sputtering process comprises at least one noble gas, preferably argon. Preferably, the process gas additionally comprises oxygen. Oxygen is necessary in the process gas in particular when the target is a target of an alloy comprising zinc and tin, preferably a target of an alloy comprising predominantly zinc and tin.

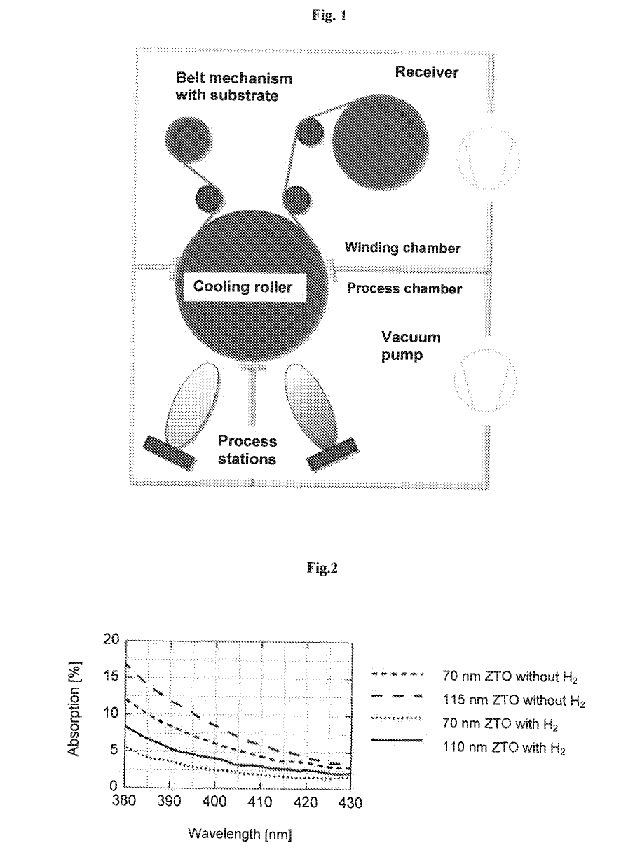

In preferred embodiments, the process according to the invention is carried out continuously. The production can particularly preferably be carried out by a simple roll-to-roll process (see e.g. FIG. 1).

Fig. I shows a diagrammatic sketch of an arrangement for carrying out such a roll-to-roll process.

There can be used as the sputtering process all conventional and known methods, such as, for example, direct-current sputtering (DC sputtering), high-frequency sputtering (HF sputtering), ion beam sputtering, magnetron sputtering or reactive sputtering. Zinc tin oxide layers are preferably produced by means of DC sputtering of the metallic target. A double magnetron arrangement is preferably chosen, which increases the stability of the process. Particularly preferably, the system is operated with a pulsed direct current between 10 and 100 kHz. The use of high-frequency sputtering (HF sputtering) is likewise possible, however. The sputtering of a ceramic zinc tin oxide target in particular is possible thereby.

The geometry of the targets that are used is variable to a large degree. Planar rectangular targets can be used. So-called tubular targets can also be employed. An increased process life is thereby ensured.

The permeation barrier coatings according to the invention, or the plastics substrates coated according to the invention, are suitable both for the production of packaging materials and, owing to their optical properties, for the production of electronic devices, in particular flexible electronic devices.

Accordingly, the present invention further provides the use of the permeation barrier coatings according to the invention, or of the plastics substrates coated according to the invention, in the production of packaging materials or in the production of electronic devices, preferably flexible electronic devices.

The packaging materials can be packaging materials for the packaging of foodstuffs or packaging materials for the packaging of industrial articles that are sensitive to oxygen and/or water vapour, such as, for example, solar cells, thin-film solar cells, lithium-based thin-film batteries, organic light-emitting diodes, transparent, optionally vacuum-insulated panels, flat organic light-emitting elements, LCD displays, TFT displays, etc.

The present invention further provides an electronic device, preferably a flexible electronic device, comprising at least one plastics substrate coated according to the invention or at least one permeation barrier coating according to the invention.

Electronic devices, in particular flexible electronic devices, can be, for example, F-readers, LCD screens, LCD television sets, ° LED display and lighting devices, touchpads, PDAs, mobile telephones, etc.

The examples which follow serve to explain the invention by way of example and are not to be interpreted as limiting.

### EXAMPLES

In a roll-to-roll vacuum coating installation, zinc tin oxide sputter layers were applied to a Makrofol® DE 1-1 polycarbonate film (film width 600 mm, film thickness 175 μm) under the following conditions:

Coating technology:
pulsed magnetron sputtering
medium-frequency pulses 50 kHz
double magnetron arrangement
zinc tin target
controlled reactive processes
power 10 kW

Zinc tin oxide (ZTO) layers in layer thicknesses of 70 nm and 115 nm were each applied by sputtering to a polycarbonate substrate without hydrogen being present in the process gas, the process gas consisting of 130 sccm oxygen and 200 sccm argon. A ZTO layer of thickness 110 nm and a ZTO layer of thickness 70 nm were each applied by sputtering to a polycarbonate substrate in the presence of 35 sccm hydrogen in the process gas, the process gas here consisting, in addition to hydrogen, of 130 sccm oxygen and 200 sccm argon. The optical transmission Tᵥᵢₛ and the layer absorption A_{blue} of the four substrates coated with the ZTO layers were determined.

The optical spectral measurement was carried out by means of a Lambda 900 spectrometer from PerkinElmer (measuring range 350-800 nm, measurement of transmission and reflection including of the substrate, integrating sphere (Ulbricht sphere) used, absorption calculated by means of transmission and reflection, corrected by the absorption of the substrate).

Calculation of the optical transmission Tᵥᵢₛ was carried out in accordance with the determination of the degree of light transmission τᵥ according to DIN EN 410 without taking account of the spectral distribution of the standard illuminant 1365.

Calculation of the layer absorption A_{blue} was carried out as the mean of the absorption spectrum, corrected by the effect of the substrate, in the wavelength range from 380 to 430 nm.

The absorption coefficient is then calculated as follows:

Absorption coefficient [l/μm]=1000·In (100/(100−A_{blue}[%]))/layer thickness [nm].

TABLE 1
Results for the zinc tin oxide layers applied by sputtering

| | Zinc tin | | | | |
|---|---|---|---|---|---|
| | oxide | Amount of | Trans- | Layer | Absorp- |
| | layer | H₂ in the | mission | absorption | tion coef- |
| Sample | thickness | process gas | Tᵥᵢₛ | A_{blue} | ficient |
| number | nm | sccm | % | % | 1/μm |
| Comparison | 70 | 0 | 76.4 | 5.3 | 0.8 |
| Example 1 | | | | | |
| Comparison | 115 | 0 | 85.7 | 7.4 | 0.7 |
| Example 2 | | | | | |
| Example 1 | 110 | 35* | 84.8 | 3.4 | 0.3 |
| Example 2 | 70 | 35* | 77.4 | 1.9 | 0.3 |

*35 sccm H₂ in the process gas corresponds to 10.6 vol. % H₂ in the process gas

The results show that, in the presence of hydrogen in the process gas, the absorption in the spectral range from 380 to 430 nm is significantly lower than without the presence of hydrogen, which significantly reduces the risk of an undesirable yellow tinge. This result is clearly apparent in FIG. 2, which shows an enlarged section of the optical absorption spectra (calculated from the transmission and reflection) between 380 and 430 nm.

The good transmission of the layers in the visible spectral range was not impaired by the presence of hydrogen in the reactive gas.

TABLE 7
Results for the permeation barrier

| | | OTR | Zinc tin oxide |
|---|---|---|---|
| Sample | WVTR | cm³/m²d | layer thickness |
| number | g/m²d | bar | nm |
| Comparison | 0.002 | 0.3 | 70 |
| Example 1 | | | |
| Comparison | 0.002 | 0.2 | 115 |
| Example 2 | | | |
| Example 1 | 0.002 | 0.3 | 110 |
| Example 2 | 0.004 | 0.2 | 70 |

A comparison of the samples produced with hydrogen in the process gas with those of equivalent layer thickness that were deposited without hydrogen merely shows a difference within the range of the measuring error for layers having a thickness of about 70 nm (Comparison Example 1 and Example 2).

For layers having a thickness of about 110 nm (Comparison Example 2 and Example 1), the water vapour transmission rate (WVTR) values are the same, and only in the oxygen transmission rate (OTR) is there again a difference within the range of the measuring error.

1.-11. (canceled)

12. A coated plastics substrate comprising a base layer comprising at least one plastics material and at least one coating of zinc tin oxide, wherein the coating of zinc tin oxide is obtained by a sputtering process in the presence of hydrogen in the process gas, the at least one plastics material does not comprise polyethylene terephthalate, and the coated plastics substrate has an absorption coefficient of less than 0.5 l/μm in the spectral range from 380 to 430 nm.

13. The coated plastics substrate according to claim 12, wherein at least one of the plastics materials in the base layer is a thermoplastic plastics material, and wherein the at least one thermoplastic plastics material does not comprise polyethylene terephthalate.

14. The coated plastics substrate according to claim 12, wherein the plastics material is a polycarbonate or a copolycarbonate based on diphenols, poly- or copoly-acrylates, poly- or copoly-methacrylates, polymers or copolymers with styrene, thermoplastic polyurethanes, polyolefins, copolycondensation products of terephthalic acid, poly- or copoly-condensation products of naphthalenedicarboxylic acid, or mixtures thereof.

15. The coated plastics substrate according to claim 12, wherein the zinc tin oxide is a chemical compound of the elements zinc, tin and oxygen, wherein the amount by mass of zinc is from 5 to 70%.

16. The coated plastics substrate according to claim 12, wherein the process gas additionally comprises oxygen.

17. The coated plastics substrate according to claim 12, wherein the thickness of the coating of zinc tin oxide is in each case from 10 to 1000 nm.

18. The coated plastics substrate according to claim 12, wherein the coating of zinc tin oxide is a permeation barrier layer for gases and vapours.

19. The coated plastics substrate according to claim 12, wherein the coated plastics substrate has an antireflection layer on the coating of zinc tin oxide.

20. The coated plastics substrate according to claim 12, wherein the plastics substrate is a plastics film.

21. A permeation barrier coating for gases and vapours comprising zinc tin oxide, wherein the coating of zinc tin oxide is obtained on a plastics substrate, which is not polyethylene terephthalate, by a sputtering process in the presence of hydrogen in the process gas, and the coated plastics substrate has an absorption coefficient of less than 0.5 l/μm in the spectral range from 380 to 430 nm.

22. An electronic device comprising at least one coated plastics substrate according to claim 12 or at least one permeation barrier coating according to claim 21.
